(19) United States
(12) Patent Application Publication
(10) Pub. No.: US 2010/0028562 A1
(43) Pub. Date: Feb. 4, 2010

(54) PLASMA GENERATING APPARATUS, DEPOSITION APPARATUS, DEPOSITION METHOD, AND METHOD OF MANUFACTURING DISPLAY DEVICE

(75) Inventors: Hitoshi NAKAGAWARA, Tokyo (JP); Takayuki Moriwaki, Tokyo (JP); Reiji Sakamoto, Tokyo (JP); Atsushi Ueno, Tokyo (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kanagawa-ken (JP)

(21) Appl. No.: 12/533,642

(22) Filed: Jul. 31, 2009

(30) Foreign Application Priority Data
Jul. 31, 2008 (JP) 2008-197879
Jun. 25, 2009 (JP) 2009-151519

(51) Int. Cl. C23C 14/28; B01J 19/12

(52) U.S. Cl. 427/576; 118/723 VE; 427/569; 422/186.21

(57) ABSTRACT

A deposition apparatus includes a plasma gun including a hollow cathode which generates a plasma beam into a vacuum chamber including an exhaust system and one or more intermediate electrodes to provide a potential gradient for the plasma beam, a focusing coil which is provided to surround the outer surface of a tube portion of the vacuum chamber located coaxially with the exit portion for outputting a plasma beam from the plasma gun and draws the plasma beam into the vacuum chamber through the tube portion, and a reflected electron feedback electrode which is placed inside the tube portion coaxially with the exit portion of the plasma gun and has a positive polarity.

### BACKGROUND OF THE INVENTION

1. Field of the Invention

The present invention relates to a plasma generating apparatus, a deposition apparatus including the plasma generating apparatus, a deposition method using the deposition apparatus, and a method of manufacturing a display device.

2. Description of the Related Art

Strong demands have recently arisen for the mass production of display devices using large substrates for displays, for example, a liquid crystal display (to be sometimes abbreviated as an “LCD” hereinafter) and a plasma display panel (to be sometimes abbreviated as a “PDP” hereinafter).

In the deposition of a thin film such as an ITO (Indium Tin Oxide) film as a transparent conductive film or an MgO (magnesium oxide) film as a front-plate electrode protective layer on a large-area substrate for a display such as a LCD or PDP, an ion plating method has attracted a great deal of attention as a deposition method replacing an EB (Electron Beam) deposition method and a sputtering method with increases in the amount of production and the resolution of panels.

Conventionally, since an MgO film or the like as an insulating film is made of an insulating deposition material, electric charges are accumulated on the surface of the material. This hinders the progress of deposition. For this reason, such a film is deposited by an RF sputtering method.

This technique cannot obtain a sufficient deposition rate. This has led to the advent of a device which deposits a film by using a plasma gun (a UR-type plasma gun (see Japanese Patent No. 1755055)).

An application of this technique is an MgO film used as a protective film for a PDP (Plasma Display Panel) as one of the above display devices.

A conventional vacuum deposition apparatus for depositing an MgO film will be described below with reference to FIGS. 4 and 5.

As shown in FIG. 5, a UR-type plasma gun 9 mounted in the arrangement in FIG. 4 includes a hollow cathode 1, one or more, for example, two intermediate electrodes (a first intermediate electrode 2 and a second intermediate electrode 3) for providing a potential gradient and a pressure gradient for a plasma beam, and a reflected electron feedback electrode 4 as an anode. The UR-type plasma gun 9 can generate a high-density columnar plasma from argon gas (to be also referred to as “Ar gas” hereinafter) introduced as a discharge gas. In this case, the reflected electron feedback electrode 4 is grounded at a potential higher than that of the hollow cathode 1. Although the arrangement shown in FIG. 4 includes two intermediate electrodes, it may include one or three or more electrodes.

The columnar plasma beam (not shown) generated by the plasma gun 9 is drawn into a vacuum chamber 13 including an exhaust system, which is a deposition chamber, by a focusing coil 6. In this case, a permanent magnet 8 having same poles facing each other can deform the columnar plasma beam into a sheet-like shape. The constituent elements of the vacuum deposition apparatus, excluding the vacuum chamber 13, constitute a plasma generating apparatus.

FIG. 4 shows a vacuum deposition apparatus 10 equipped with a conventional plasma generating apparatus.

A plasma beam 7 deformed into a sheet-like shape is guided to the surface of a deposition material 22 along the lines of magnetic force generated by a drawing magnet 21 placed below a volatile material tray 23 in the vacuum chamber 13.

The reflected electron feedback electrode 4 has, in its center, a through hole 4a for allowing the plasma beam 7 to pass through. The reflected electron feedback electrode 4 is placed in a short tube portion 12. The short tube portion 12 is a portion of the vacuum chamber 13 which protrudes to the plasma gun 9 side. The focusing coil 6 is placed around the outer surface of the short tube portion 12 so as to be spaced apart from it. Note that the short tube portion 12 is placed coaxially with the exit portion of the plasma gun 9 which outputs the plasma beam 7.

An insulating tube 5 as a consumable part to secure insulation is placed in the through hole 4a of the reflected electron feedback electrode 4 to prevent the plasma beam 7 from directly entering the reflected electron feedback electrode 4.

The plasma beam 7 exiting from the hollow cathode 1 of the plasma gun 9 into the vacuum chamber 13 passes through the through hole 4a of the reflected electron feedback electrode 4. The insulating tube 5 is placed to surround the periphery of the plasma beam 7.

The plasma beam 7 emitted from the plasma gun 9 is guided to the magnetic field generated by the focusing coil 6 and irradiates the surface of the deposition material 22. Secondary electrons emitted from the deposition material 22 are guided to flow against the same magnetic field and strike the reflected electron feedback electrode 4 as an anode, and are fed back to a power supply 50.

An anti-deposition plate 11 and the like which cover the inside of the vacuum deposition apparatus 10 are all set at a floating potential so as to reliably feed secondary electrons back to the reflected electron feedback electrode 4. These arrangements can solve the above problem, and hence can continue deposition on the surface of a substrate 20 while preventing electric charges of one direction from being kept accumulated on the surface of the deposition material 22.

The particles evaporated from the surface of the deposition material 22 are ionized with a considerably high probability. Like secondary electrons, some of the ionized particles are guided to a magnetic field formed inside the vacuum deposition apparatus 10 and strike the reflected electron feedback electrode 4. Consequently, an insulating film of the deposition material 22 is deposited on the surface of the reflected electron feedback electrode 4. However, Ar ions and the like existing inside the vacuum deposition apparatus 10 sputter the insulating film. This makes it possible to secure a feedback path of the reflected electron feedback electrode 4.

In a manufacturing process for a large-area substrate for a display such as an LCD or PDP, the power supplied to the plasma gun 9 has become much larger than that in the prior art with requirements for higher deposition rates in the vacuum deposition apparatus 10 described above.

In addition, since the continuous running time of the vacuum deposition apparatus 10 prolongs, the integral power consumption used in the plasma gun 9 per maintenance cycle increases as compared with the prior art.

As the power to be supplied increases, the plasma density and energy of the columnar plasma beam generated by the plasma gun 9 increase. This will greatly increase the damage which the insulating tube 5 placed in the reflected electron feedback electrode 4 suffers from a plasma beam.

As the insulating tube 5 wears, the inner diameter of the insulating tube 5 increases, resulting in a reduction in the plasma density of a plasma beam. A reduction in plasma density becomes a factor of instability that reduces the amount of evaporation from the deposition material 22.

In the conventional structure, as shown in FIG. 5, there is a gap between the insulating tube 5 placed in the through hole 4a of the reflected electron feedback electrode 4 and a G2 collar 3a placed on the second intermediate electrode 3 placed closest to the reflected electron feedback electrode 4. In this case, the G2 collar 3a is the inner surface portion of the second intermediate electrode 3 and is an exchangeable portion made of a conductive material. The G2 collar 3a therefore forms part of the second intermediate electrode 3. If the G2 collar 3a need not be exchangeable, it can be integrated with the main part of the second intermediate electrode 3. Since the surface potential of the insulating tube 5 existing in plasma is negative, Ar ions introduced in the vacuum chamber 13 as a deposition chamber sputter the surface. This leads to wear of the insulating tube 5.

### SUMMARY OF THE INVENTION

The present invention provides a plasma generating apparatus, a deposition apparatus, a deposition method, and a method of manufacturing a display device, which suppress the wear of an insulating tube as a consumable part of the deposition apparatus, and can reduce the running cost by prolonging the continuous running time of a plasma gun which is affected by the amount of wear of the insulating tube.

According to one aspect of the present invention, there is provided a deposition apparatus which comprises a plasma gun including a hollow cathode which generates a plasma beam into a vacuum chamber including an exhaust system and not less than one intermediate electrode to provide a potential gradient for the plasma beam, a focusing coil which is provided to surround an outer surface of a tube portion of the vacuum chamber located coaxially with an exit portion for outputting the plasma beam from the plasma gun and draws the plasma beam into the vacuum chamber through the tube portion, and a reflected electron feedback electrode which is placed inside the tube portion coaxially with the exit portion of the plasma gun and has a positive polarity, and irradiates a deposition material in the vacuum chamber with the plasma beam to deposit a thin film having the deposition material on a substrate placed in the vacuum chamber by heating and evaporating the deposition material, wherein an insulating tube provided on an inner surface portion of the reflected electron feedback electrode which is grounded and has a potential higher than a potential of the hollow cathode is in electrical contact with the intermediate electrode placed closest to the reflected electron feedback electrode.

According to another aspect of the present invention, there is provided a plasma generating apparatus comprising: a plasma gun including a hollow cathode which generates a plasma beam into a vacuum chamber including an exhaust system and not less than one intermediate electrode to provide a potential gradient for the plasma beam; a focusing coil which is provided to surround an outer surface of a tube portion of the vacuum chamber located coaxially with an exit portion for outputting the plasma beam from the plasma gun and draws the plasma beam into the vacuum chamber through the tube portion; and a reflected electron feedback electrode which is placed inside the tube portion coaxially with the exit portion of the plasma gun and has a positive polarity, wherein an insulating tube provided on an inner surface portion of the reflected electron feedback electrode which is grounded and has a potential higher than a potential of the hollow cathode is in electrical contact with the intermediate electrode placed closest to the reflected electron feedback electrode.

According to the present invention, since the insulating tube is in electric contact with the intermediate electrode placed closest to the reflected electron feedback electrode, electrons charged on the surface of the insulating tube flow into the intermediate electrode. This can set the surface of the insulating tube at a high potential. This makes it possible to reduce the amount of ions injected to the surface of the insulating tube by using a discharge gas. Since the wear of the insulating tube due to sputtering by discharge gas ions can be reduced, the wear's amount of the insulating tube can be decreased, and the service life of the insulating tube can be prolonged.

Further features of the present invention will become apparent from the following description of exemplary embodiments with reference to the attached drawings.

### BRIEF DESCRIPTION OF THE DRAWINGS

FIG. 1 is a schematic side view for explaining an example of a plasma generating apparatus and a vacuum deposition apparatus using it according to an embodiment of the present invention;

FIG. 2 is a schematic side view for explaining an example of a plasma generating apparatus according to the embodiment of the present invention;

FIG. 3A is a schematic side view for explaining an example of a plasma generating apparatus according to the embodiment of the present invention in a case in which the inside of an insulating tube 5 is coated with a conductive substance;

FIG. 3B is an enlarged view of the insulating tube 5 which is coated with a conductive substance;

FIG. 4 is a schematic side view for explaining an example of a conventional plasma generating apparatus and a vacuum deposition apparatus using it; and

FIG. 5 is a schematic side view for explaining an example of a conventional plasma generating apparatus.

### DESCRIPTION OF THE EMBODIMENTS

The best mode for carrying out the present invention will be described in detail below with reference to the accompanying drawings.

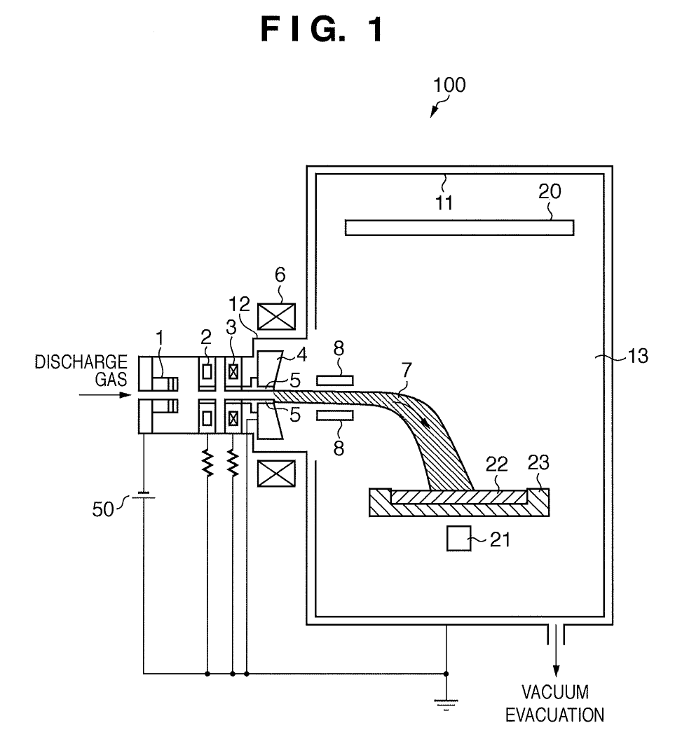

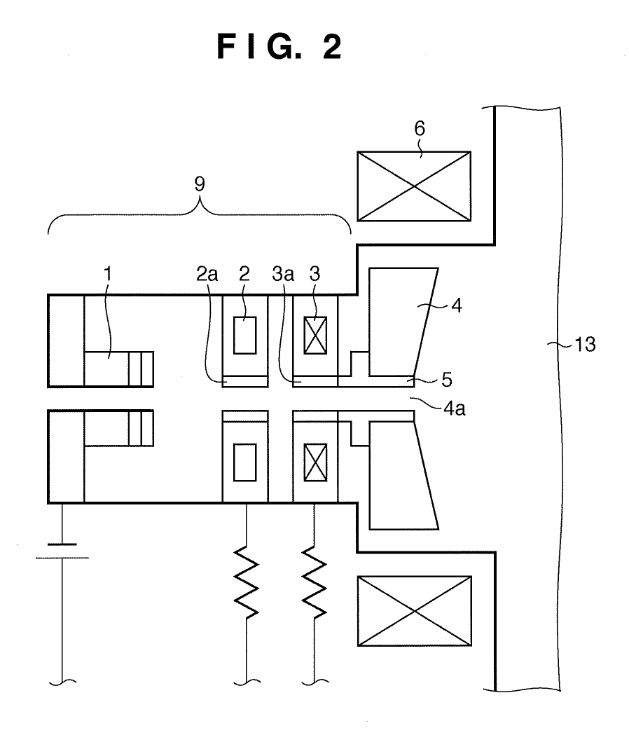

FIG. 1 is a side view showing the schematic arrangement of an example of a vacuum deposition apparatus 100 according to the present invention. FIG. 2 is a side view showing the schematic arrangement of a plasma generating apparatus mounted in the vacuum deposition apparatus in FIG. 1.

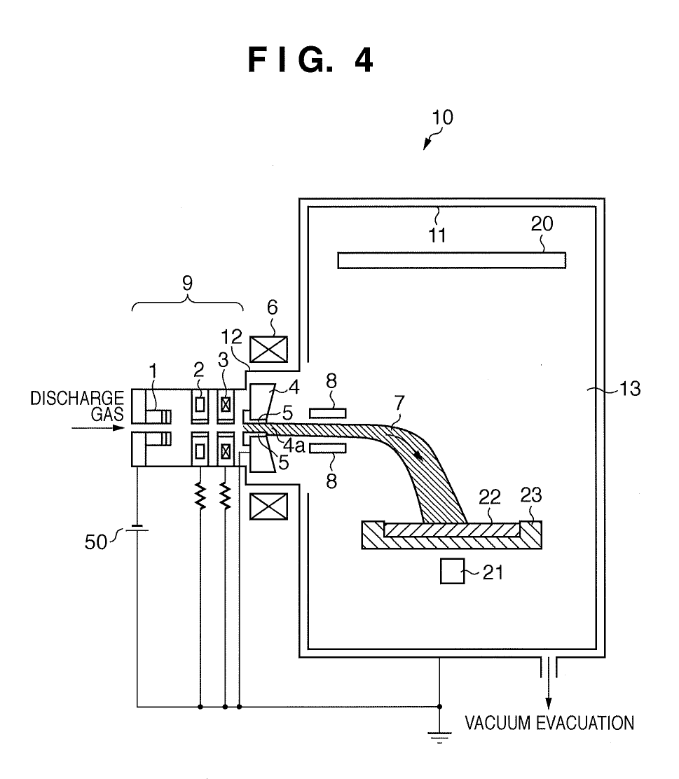

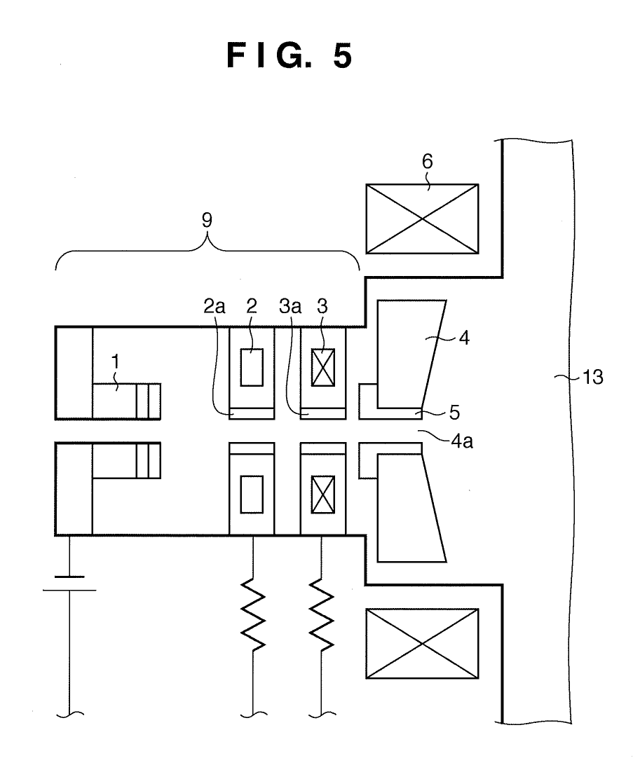

The basic arrangements of the vacuum deposition apparatus 100 and plasma generating apparatus respectively shown in FIGS. 1 and 2 are the same as those of the vacuum deposition apparatus 10 and plasma generating apparatus respectively shown in FIGS. 4 and 5, and hence a repetitive description will be omitted.

Note, however, that the vacuum deposition apparatus 100 and plasma generating apparatus according to the present invention differ from those of the prior art in that a G2 collar 3a is in contact with an insulating tube 5. This difference will be specifically described below.

The plasma generating apparatus according to the embodiment of the present invention shown in FIG. 2, includes, for example, two intermediate electrodes (a first intermediate electrode 2 and a second intermediate electrode 3). The G2 collar 3a placed inside the second intermediate electrode 3 located closest to a reflected electron feedback electrode 4 is in contact with the insulating tube 5 placed in a through hole 4a of the reflected electron feedback electrode 4. The G2 collar 3a is part of the second intermediate electrode 3, and is in contact with the main part of the second intermediate electrode 3. The insulating tube 5 is therefore in contact with the second intermediate electrode 3.

Bringing the G2 collar 3a into contact with the insulating tube 5 placed in contact with the reflected electron feedback electrode 4 will make electrons charged on the surface of the insulating tube 5 flow into the G2 collar 3a. Therefore, the second intermediate electrode 3, which is an intermediate electrode placed closest to the reflected electron feedback electrode 4, is brought into electric contact with the insulating tube 5 to make electrons also flow into the second intermediate electrode 3. Consequently, the surface potential of the insulating tube 5 becomes higher than that when the insulating tube 5 is not in contact with the G2 collar 3a. It is possible to increase the potential of the through hole 4a of the reflected electron feedback electrode 4 to near the potential of the G2 collar 3a of the second intermediate electrode 3. Increasing the surface potential of the insulating tube 5 can reduce the amount of Ar ions injected to the surface of the insulating tube 5. This makes it possible to reduce the damage which the surface of the insulating tube 5 suffers from a plasma beam. As a consequence, the amount of wear of the insulating tube 5 can be reduced.

The vacuum deposition apparatus 100 in FIG. 1 is equipped with the plasma generating apparatus in FIG. 2.

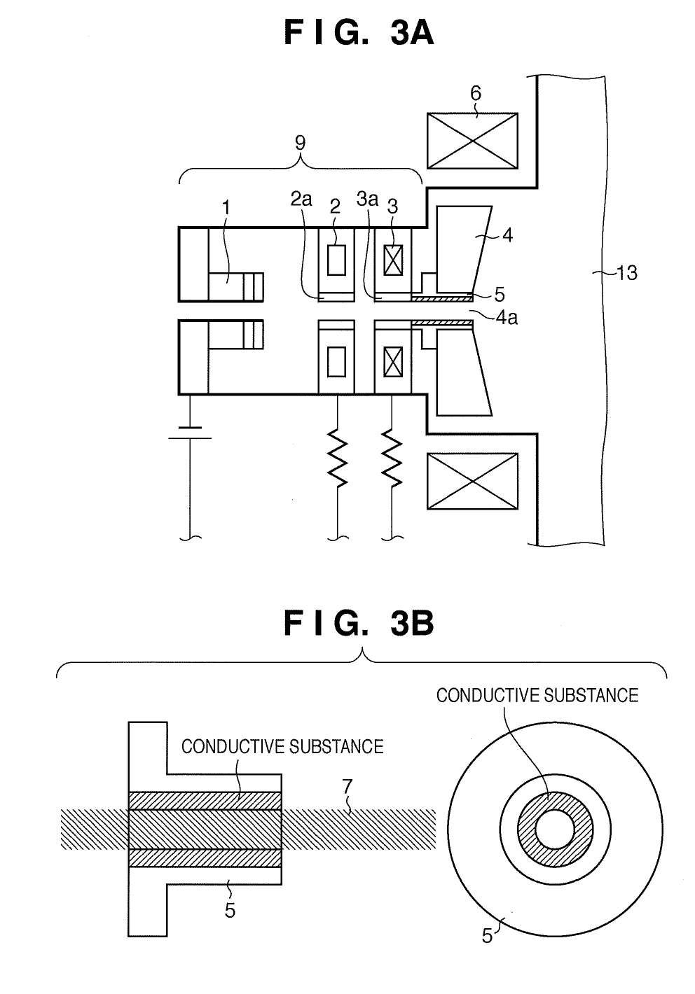

FIG. 3A is a view exemplifying a case in which the inner surface portion of the insulating tube 5 is coated with a conductive substance in the plasma generating apparatus in FIG. 2.

FIG. 3B is an enlarged view of the insulating tube 5 shown in FIG. 3A. The left side of FIG. 3B is a side view of the insulating tube 5. The right side of FIG. 3B is a view of the insulating tube 5 when viewed from the traveling direction of a plasma beam.

In this case, the inner surface portion of the insulating tube 5 is coated with a conductive substance. As this conductive substance, for example, a material like carbon can be selected, which has heat resistance, allows easy deposition of a thin film on the inner surface portion, and can improve conductivity.

### EXAMPLE 1

A plasma beam was generated for a predetermined period of time by using the vacuum deposition apparatus 100 shown in FIG. 1. The weight of the wear's amount of the insulating tube 5 in the reflected electron feedback electrode 4 at this time was measured. A comparison target is the insulating tube 5 in the arrangement of the vacuum deposition apparatus 10 shown in FIGS. 4 and 5. That is, the insulating tube 5 as the comparison target is not in contact with the G2 collar 3a of the second intermediate electrode 3 which is placed closest to the reflected electron feedback electrode 4.

The conditions for the generation of plasma beams were the same in both the apparatuses. Argon gas (to be also referred to as “Ar gas” hereinafter) was introduced as a gas for a plasma into a plasma gun 9. An Ar gas introduction system (not shown) was used to introduce Ar gas into a vacuum chamber 13 as a deposition chamber. A plasma beam was generated under the following conditions:

input power: 20 kW

discharge pressure: 0.1 Pa

Ar flow rate: 11 sccm (0.18 ml/sec)

As a result, it was confirmed that the amount (rate) of wear of the insulating tube 5 used in the plasma generating apparatus of the vacuum deposition apparatus 100 according to the embodiment of the present invention was reduced to about ⅕ that of the insulating tube 5 used in the conventional plasma generating apparatus. Assume that the insulating tube 5 needs to be replaced at the amount of wear caused on the conventional insulating tube 5. In this case, the embodiment of the present invention can prolong the replacement cycle of the insulating tube 5 by about five times and reduce the running cost.

The vacuum deposition apparatus 100 shown in FIGS. 1 and 2 is used to deposit a magnesium oxide (MgO) film as a protective film for a PDP as one of display devices. An example of a method of manufacturing this film will be described below.

Argon gas was introduced as a gas for a plasma (discharge gas) into the plasma gun 9 as indicated by the arrow shown in FIG. 1. Oxygen gas was introduced into the vacuum chamber 13 through an oxygen gas introduction tube (not shown) to deposit a film on a substrate 20 as a film deposition object. The substrate 20 was held by a substrate holder (not shown) so as to face a deposition material 22.

material: magnesium oxide (MgO)

film thickness: 12000 Å

discharge pressure: 0.1 Pa

Ar flow rate: 11 sccm (0.18 ml/sec)

O₂ flow rate: 400 sccm (6.7 ml/sec)

This prevented the instability, that is, a decrease in the amount of evaporation of a deposition material due to a decrease in the plasma density of a plasma beam, and hence could stably deposit an MgO film as a protective film for a display device.

The plasma generating apparatus, the deposition apparatus using it, the deposition method, and the method of manufacturing a display device according to the present invention are suitable, for example, for a reduction in running cost in the manufacture of a plasma display panel or the like.

According to this embodiment, since the insulating tube is in electrical contact with the intermediate electrode placed closest to the reflected electron feedback electrode, electrons charged on the surface of the insulating tube flow into this intermediate electrode. Therefore, the surface of the insulating tube can be set at a high potential. This can reduce the amount of Ar ions injected to the surface of the insulating tube, and hence can decrease the wear rate of the insulating tube and prolong the service life of the insulating tube.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-197879, filed Jul. 31, 2008, and Japanese Patent Application No. 2009-151519, filed Jun. 25, 2009, which are hereby incorporated by reference herein in their entirety.

What is claimed is:

1. A deposition apparatus which comprises:
a plasma gun including a hollow cathode which generates a plasma beam into a vacuum chamber including an exhaust system and not less than one intermediate electrode to provide a potential gradient for the plasma beam,
a focusing coil which is provided to surround an outer surface of a tube portion of the vacuum chamber located coaxially with an exit portion for outputting the plasma beam from said plasma gun and draws the plasma beam into the vacuum chamber through the tube portion, and
a reflected electron feedback electrode which is placed inside the tube portion coaxially with the exit portion of said plasma gun and has a positive polarity, and
irradiates a deposition material in the vacuum chamber with the plasma beam to deposit a thin film having the deposition material on a substrate placed in the vacuum chamber by heating and evaporating the deposition material,
wherein an insulating tube provided on an inner surface portion of said reflected electron feedback electrode which is grounded and has a potential higher than a potential of the hollow cathode is in electrical contact with the intermediate electrode placed closest to said reflected electron feedback electrode.

2. The apparatus according to claim 1, wherein the insulating tube surrounds a periphery of the plasma beam inside the tube portion.

3. The apparatus according to claim 1, wherein an inner surface portion of the insulating tube is coated with a conductive substance.

4. A deposition method comprising a deposition step of depositing a film on the substrate by using a deposition apparatus defined in claim 1.

5. The method according to claim 4, wherein the film comprises an MgO film.

6. A method of manufacturing a display device, the method comprising a deposition step using a deposition method defined in claim 4.

7. A plasma generating apparatus comprising:
a plasma gun including a hollow cathode which generates a plasma beam into a vacuum chamber including an exhaust system and not less than one intermediate electrode to provide a potential gradient for the plasma beam;
a focusing coil which is provided to surround an outer surface of a tube portion of the vacuum chamber located coaxially with an exit portion for outputting the plasma beam from said plasma gun and draws the plasma beam into the vacuum chamber through the tube portion; and
a reflected electron feedback electrode which is placed inside the tube portion coaxially with the exit portion of said plasma gun and has a positive polarity,
wherein an insulating tube provided on an inner surface portion of said reflected electron feedback electrode which is grounded and has a potential higher than a potential of the hollow cathode is in electrical contact with the intermediate electrode placed closest to said reflected electron feedback electrode.

8. The apparatus according to claim 7, wherein the insulating tube surrounds a periphery of the plasma beam inside the tube portion.

9. The apparatus according to claim 7, wherein an inner surface portion of the insulating tube is coated with a conductive substance.
